(19) United States
(12) Patent Application Publication
(10) Pub. No.: US 2004/0121550 A1
(43) Pub. Date: Jun. 24, 2004

(54) Method for creating barriers to metal contamination in silicon oxides

(76) Inventors: Vladimir Zubkov, Mountain View, CA (US); Grace Sun, Sunnyvale, CA (US); Sheldon Aronowitz, San Jose, CA (US)

Correspondence Address: LSI LOGIC CORPORATION, 1621 BARBER LANE, MS: D-106 LEGAL, MILPITAS, CA, 95035, US

(21) Appl. No.: 10/325,373

(22) Filed: Dec. 19, 2002

(51) Int. Cl. H01L 21/336; H01L 21/31; H01L 21/469

(52) U.S. Cl. 438/287; 438/785

(57) ABSTRACT

A method of creating a barrier to metal contamination in interconnect and gate oxides comprises ion implantation of an alkaline earth metal into the silicon dioxide. The presence of the implanted alkaline earth metal, preferably calcium, traps metal contaminants and thereby creates a barrier to further contamination. Alternatively, the alkaline earth metal can be implanted into the silicon dioxide as a low energy plasma. The implantation of atomic calcium into gate oxide serves to trap boron and thereby minimize boron diffusion from a polysilicon gate into silicon.

### BACKGROUND OF THE INVENTION

Most processes for the preparation of surfaces in semiconductor manufacturing use acids, bases, and solvents. Although the chemical purity of these substances has improved to very low level of ion and metal contamination, alkali metals like Na and transition metals like Fe, Ni, and Cu can cause interconnect and gate-oxide degradation and current leakage even at these low levels. New technological processes such as metal gates and metal silicides, among others, may further lead to an increase in metal contamination of interconnects and gate oxides. Plasma etching, commonly used to define structures, also can introduce contaminants. Contamination control demands serious efforts and complicates the processing technology in device manufacturing. Accordingly, a need exists for a method to trap metal cations to decrease metal contamination.

Additionally, as silicon devices become smaller, it becomes necessary to minimize dopant diffusion (particularly boron) from a polysilicon gate to silicon. The conventional solution has been to create a hardened gate oxide by incorporating nitrogen into the oxide.

Various thermal oxynitridation processes are done by growing SiO₂ film with NH₃, N₂O, or NO present. The difficulty is that only a relatively low percentage of nitrogen can be incorporated (usually less than six atomic percent), resulting in a barrier that is only partially effective. In addition, nitrogen near the silicon/dielectric interface increases the number of fixed-charge density and electron traps produced as the processing temperature increases. These charges and traps shift threshold voltages, degrade inversion-layer mobilities, and reduce stability against hot-carrier stressing.

These disadvantages in the use of thermal oxynitridation has motivated the use of another process: Plasma Enhanced Chemical Vapor Deposition (PECVD). To form a thin silicon oxynitride layer using PECVD, the oxide layer is exposed with mixtures such as SiH₄, NH₃, N₂O, N₂ and NO. PECVD using an NH₃ mixture, however, forms hydrogen that induces bond-breaking behaviors and results in a hot-electron effect where energetic electrons break silicon-hydrogen bonds at the silicon/oxide interface. PECVD with N₂O and NO, furthermore, can reduce the amount of hydrogen, but the formed film has high stress between the nitride and the oxide. In addition, experimentally both methods form high concentration of nitrogen in the oxide/silicon interface, as illustrated in FIG. 2. Nitrogen can then form Si₃N₄, which obstructs the formation of oxide. Secondly, nitrogen can diffuse to the silicon/oxide interface and shift the threshold voltage.

Accordingly, a need exists for a barrier against boron diffusion that avoids the limitations of the prior art in a cost-effective way.

### OBJECTS AND SUMMARY OF THE INVENTION

The invention consists of the implantation of an alkaline earth metal, preferably calcium, to trap boron and metal contaminants. An alkaline earth metal is implanted, by ion implantation, into interconnects or gate oxides to trap metal cations. All harmful metal contaminants are strongly attracted to Ca, several of these contaminants are strongly attracted to Sr, and Mg and Ba likely have similar effects. The attraction of the metal contaminants to the alkaline earth metal leads to a barrier to contamination, because the alkaline earth metal traps the contaminant. Because most contamination will involve the intermetallic dielectric layers which are comparatively thick, conventional implant energies (three keV or greater) can be used. On the other hand, gate dielectrics are extremely thin and therefore only very low energy (about 10 to 50 eV) implants can be employed. For example, calcium is implanted, as a low-energy plasma, into silicon oxide to create a barrier to boron diffusion due to the strong attraction between the boron and the environment created by the presence of calcium.

It is an object of the invention to provide easily-achieved barriers to metal cation diffusion in oxides to decrease contamination. It is a further object of the present invention to provide a method of preparing a gate oxide barrier that suppresses boron diffusion into the silicon oxide.

### BRIEF DESCRIPTION OF THE DRAWINGS

The organization and manner of the structure and operation of the invention, together with further objects and advantages thereof, may best be understood by reference to the following description, taken in connection with the accompanying drawing, wherein

FIG. 1 is a table listing the interactions energies of cations with a silicon oxide supercell containing Ca or Sr, and

FIG. 2 is an illustration of a gate oxide barrier, showing the nitrogen distribution as occurs in the prior art and as desired to avoid the problems caused by nitrogen at the oxide/silicon interface.

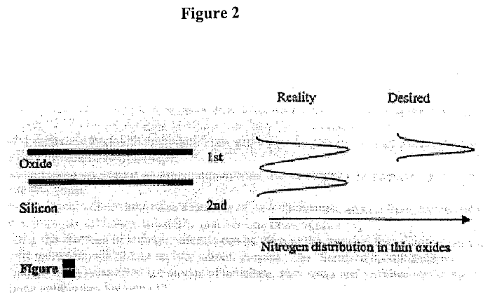

### DESCRIPTION OF THE INVENTION

While the invention may be susceptible to embodiment in different forms, there is shown in the drawings, and herein will be described in detail, a specific embodiment with the understanding that the present disclosure is to be considered an exemplification of the principles of the invention, and is not intended to limit the invention to that as illustrated and described herein.

The central point of the invention is the use of ion implantation of atomic Ca or Sr into silicon oxide. Ca and Sr insert themselves into siloxane rings that are the basic units of amorphous silicon oxide. (Rings contain from two to nine Si—O groups). The inserted Ca or Sr create dilute layers of Ca or Sr in oxide that serve as a trap for metal cations. Quantum mechanical modeling shows strong attraction between Ca or Sr and metal cations. This strong attraction should lessen metal penetration into oxide and thus diminish contamination.

To obtain optimal trapping (barrier) properties for interconnects, it is necessary to generate concentrations of inserted Ca or Sr atoms that approximately equal one Ca or Sr atom per ten to twelve Si—O groups. Suitable combinations of dose and energy for implanted Ca or Sr are 2×10¹⁵ X/cm² at 10 keV or 4×10¹⁵ X/cm² at 20 keV (where X═Ca or Sr). At 20 keV, the peak concentration of Ca will be 2.3×10²¹ Ca/cm³ and it lowers only to 1.4×10²¹ Ca/cm³ within 70 Å around the peak concentration. In the case of Sr at 20 keV, the peak concentration of Sr will be 4×10²¹/cm³ and it lowers only to 9×10²⁰ Ca/cm³ within 70 Å around the peak concentration.

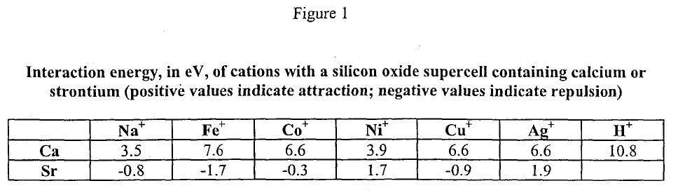

Ab initio quantum mechanical calculations for a silicon oxide supercell containing several siloxane rings is considered within the framework of periodic boundary conditions. Ab initio calculations showed that interaction of atomic Ca or Sr with a silicon oxide supercell might lead to a position of Ca or Sr atoms in the siloxane ring center. In the table shown in FIG. 1, energies of attraction (or repulsion: negative values) of various, mostly metal, cations with atoms Ca or Sr in silicon oxide are cited.

The presence of Ca atoms in oxide leads to a significant attraction of cations to Ca. Cation diffusion is determined on the microscopic level by the barrier energy Eₐ for a cation jumping from one stable position to another one. Attraction to Ca sharply increases the barrier to cation jumping because the cation would have to overcome an attraction to Ca which in most cases is more than 3 eV.

In the case of Sr similar attraction was found only for Ni⁺, Ag⁺, and neutral boron. So of these two alkaline earths only Ca would serve as a barrier to metal penetration for a broad spectrum of metal cations. The use of Sr in this respect is restricted to Ni⁺, Ag⁺, and neutral boron. Similarly, other alkaline earths, Mg and Ba, could be considered as candidates for implantation into silicon oxide for preventing metal contamination in interconnects.

As an alternative to ion implantation, low energy plasmas formed by these alkaline earths could be used to create thin alkaline earth rich layers just below the surface of gate oxides thus facilitating decrease in contamination of gate oxides by metal cations in the case of metal gates.

Similarly, atomic calcium has several advantages compared to nitrogen as an agent to suppress boron diffusion through silicon oxide. First, calcium diffuses less than nitrogen because it has a larger size and a greater mass than nitrogen. The quantity of calcium that diffuses into the silicon/oxide interface is then substantially reduced or entirely suppressed which eliminates problems found in the second interface created with silicon oxynitride. Second, calcium interacts weakly with electrons so that electron entrapment becomes unlikely. Electron entrapment is undesirable since it causes a drift in threshold voltage.

The calcium layer is formed by implantation in the oxide using a low energy plasma. Combinations of dose and energy for implanted calcium are around 2×10¹⁴ calcium/cm² at 10 to 20 eV.

Calculations with SiO₂ structures show that calcium is stable in the center of a siloxane ring. The interaction between calcium and boron (or B⁺) is attractive, as high as three eV (or five eV). Such strong attraction energy provides boron entrapment and prevents boron from diffusing into the silicon. About one calcium atom in every four rings is desirable to optimize its use as a barrier layer.

Considering the advantages of a calcium barrier layer along with the results using ab initio quantum mechanical calculations, the conclusion is that calcium should produce a more desirable barrier over a barrier formed with nitrogen implantation of plasma or thermal processing.

We claim:

1. A method of preventing metal contamination in gate oxides in semiconductor devices, comprising ion implantation of an alkaline earth metal into silicon oxide.

2. The method of claim 1, wherein said alkaline earth metal is calcium.

3. The method of claim 1, wherein said alkaline earth metal is strontium.

4. The method of claim 1, wherein said alkaline earth metal is magnesium.

5. The method of claim 1, wherein said alkaline earth metal is barium.

6. A method of preventing metal contamination in gate oxides in semiconductor devices, comprising creating a layer below the surface of a gate oxide by application of a low energy plasma of an alkaline earth metal.

7. The method of claim 6, wherein said alkaline earth metal is calcium.

8. The method of claim 6, wherein said alkaline earth metal is strontium.

9. The method of claim 6, wherein said alkaline earth metal is magnesium.

10. The method of claim 6, wherein said alkaline earth metal is barium.

11. A gate oxide barrier to minimize dopant diffusion from polysilicon gates to silicon, comprising atomic calcium implanted into silicon oxide.

12. The gate oxide barrier of claim 11, wherein said atomic calcium is implanted as a low energy plasma.
